(19) United States
(12) Patent Application Publication
(10) Pub. No.: US 2024/0234487 A1
(43) Pub. Date: Jul. 11, 2024

(54) DEEP TRENCH CAPACITORS

(71) Applicant: Taiwan Semiconductor Manufacturing Company, Ltd., Hsinchu (TW)

(72) Inventors: Wei-Hang Huang, Kaohsiung City (TW); Chung-Liang Cheng, Hsinchu (TW)

(21) Appl. No.: 18/320,020

(22) Filed: May 18, 2023

Related U.S. Application Data
(60) Provisional application No. 63/483,037, filed on Feb. 3, 2023.
(60) Provisional application No. 63/479,322, filed on Jan. 10, 2023.

(51) Int. Cl. H01L 27/146

(52) U.S. Cl. CPC H01L 28/91; H01L 27/14603; H01L 27/14634; H01L 27/14636; H01L 27/1469

(57) ABSTRACT

Semiconductor structures and methods of forming the same are provided. A semiconductor structure of the present disclosure includes a contact feature disposed in a first dielectric layer, a first etch stop layer (ESL) over the contact feature and the first dielectric layer, a second dielectric layer over the first ESL, a second ESL over the second dielectric layer, a third dielectric layer over the second ESL, a third ESL over the third dielectric layer, a fourth dielectric layer over the third ESL, and a capacitor. The capacitor includes a bottom electrode layer continuously extending along a top surface of the fourth dielectric layer and vertically through the fourth dielectric layer, the third ESL, the third dielectric layer, the second ESL, the second dielectric layer, and the first ESL, an insulator layer disposed over the bottom electrode, and a top electrode layer disposed over the insulator layer.

### PRIORITY DATA

This application claims priority to U.S. Provisional Patent Application Ser. No. 63/479,322, filed Jan. 10, 2023, as well as U.S. Provisional Patent Application Ser. No. 63/488,037, filed Feb. 3, 2023, each of which is herein incorporated by reference in its entirety.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed. In the course of IC evolution, functional density (i.e., the number of interconnected devices per chip area) has generally increased while geometry size (i.e., the smallest component that can be created using a fabrication process) has decreased.

As the geometry size of IC devices decreases, passive devices that require large surface areas are moved to back-end-of-line (BEOL) structures. Metal-Insulator-Metal (MIM) capacitors are among examples of such passive devices. MIM capacitors may have a two-dimensional construction or a three-dimensional construction. The latter requires formation of a trench and deposition of capacitor layers in the trench. Although existing MIM structures and the fabrication process thereof have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1 illustrates a flowchart of a method for forming an MIM capacitor, according to one or more aspects of the present disclosure.

FIGS. 2-15 are a schematic cross-sectional view of a workpiece undergoing fabrication according to the method of FIG. 1, according to various aspects of the present disclosure.

FIG. 16 illustrates a flowchart of a method for forming an image sensor element, according to one or more aspects of the present disclosure.

FIG. 17 is a schematic cross-sectional view of a top wafer that includes photodiodes, according to various aspects of the present disclosure.

FIG. 18 is a schematic cross-sectional view of a middle wafer that includes MIM capacitors similar to the one formed using the method of FIG. 1, according to various aspects of the present disclosure.

FIG. 19 is a schematic cross-sectional view of the middle wafer in FIG. 18 bonded to the top wafer in FIG. 17, according to various aspects of the present disclosure.

FIG. 20 is a schematic cross-sectional view of the bonded wafer stack in FIG. 19 where the middle wafer is thinned, according to various aspects of the present disclosure.

FIG. 21 is a schematic cross-sectional view of the bonded wafer stack in FIG. 20 where bonding features are formed over the middle wafer, according to various aspects of the present disclosure.

FIG. 22 is a schematic cross-sectional view of a bottom wafer that includes logic transistors, according to various aspects of the present disclosure.

FIG. 23 is a schematic cross-sectional view of a bottom wafer bonded to the wafer stack in FIG. 21, according to various aspects of the present disclosure.

FIG. 24 is a schematic cross-sectional view of an image sensor structure formed from the wafer stack shown in FIG. 23, according to various aspects of the present disclosure.

FIG. 25 includes schematic top-view illustrations of trim-type MIM capacitors, according to various aspects of the present disclosure.

FIG. 26 includes schematic top-view illustrations of comb-type MIM capacitors, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Complementary metal-oxide-semiconductor (CMOS) image sensors (CIS) have gained popularity in recent years. As pixels of a CIS become smaller to achieve higher resolution, the amount of charge that can be stored within a single pixel, otherwise known as the full well capacity (FWC), may become smaller as well. A capacitor may be integrated with a CIS to accumulate overflow photoelectrons. In general, a greater capacitance is desired because the amount of charge is proportional to the capacitance. Additionally, read noise is inversely related to the capacitance. Furthermore, the capacitors may store the photoelectrons before the detected photo sensitive signal is processed by an analog-to digital converter (ADC) in order to realize a global shutter CIS.

The present disclosure provides an MIM capacitor that vertically extends through more than one metal layer to increase the areas of the conductor plates, thereby increasing the capacitance of the resultant capacitor. The present disclosure also provides methods of forming an MIM capacitor. The methods of the present disclosure include formation of a cap layer or a protection layer to protect edges of a pilot trench opening before the pilot trench opening is extended toward an underlying contact feature. The cap layer prevents undesirable widening of the trench opening. The method of the present disclosure also include depositing layers in the capacitor using a deposition-etch-deposition-etch-deposition (DEDED) method to reduce void formation. To prevent electrical shorting between the electrode layers of the MIM capacitor, method of the present disclosure pattern a bottom electrode layer and a top electrode layer separately with lateral offset. A method to form a CIS with MIM capacitors formed using methods of the present disclosure is also described. The MIM capacitors integrated in a CIS may be trim-type, comb-type, or both to control wafer warpage.

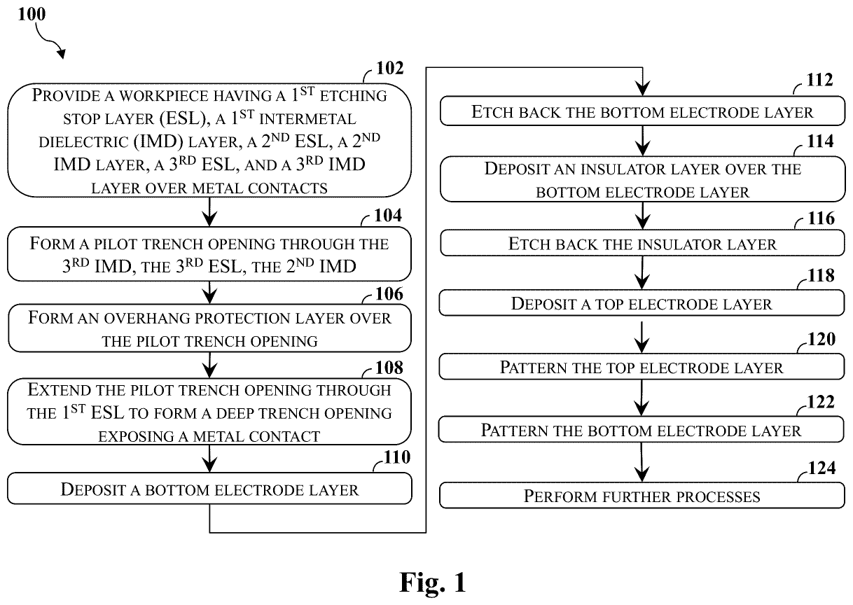

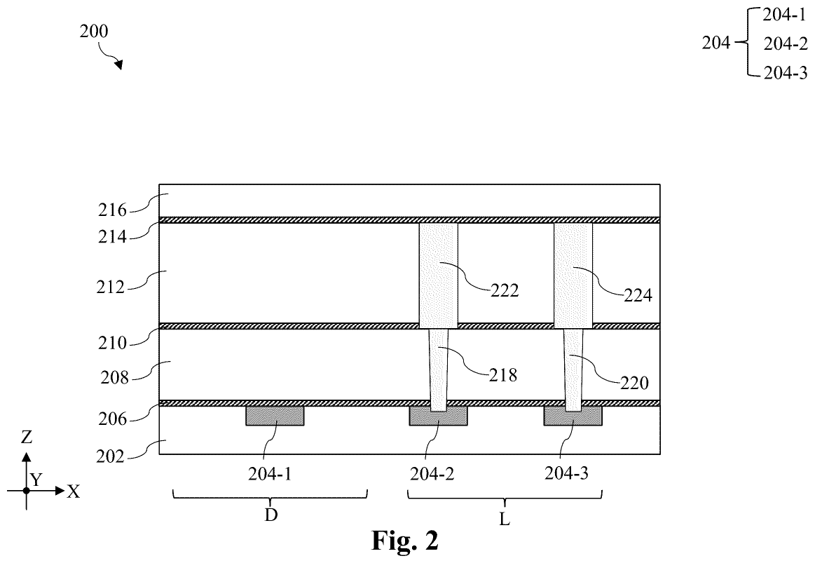

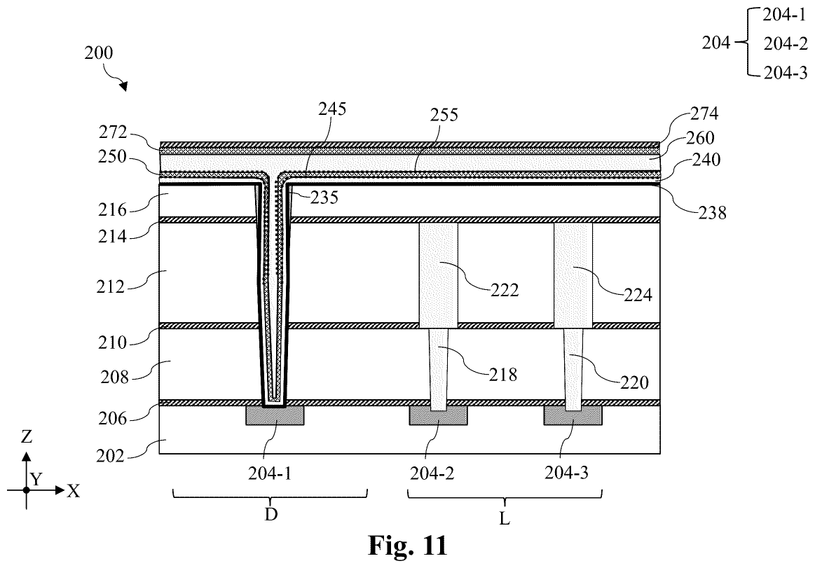

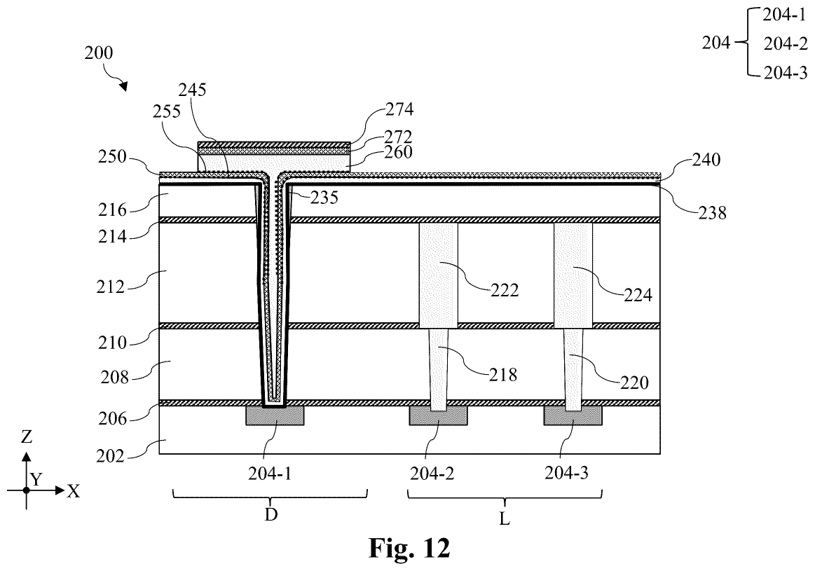

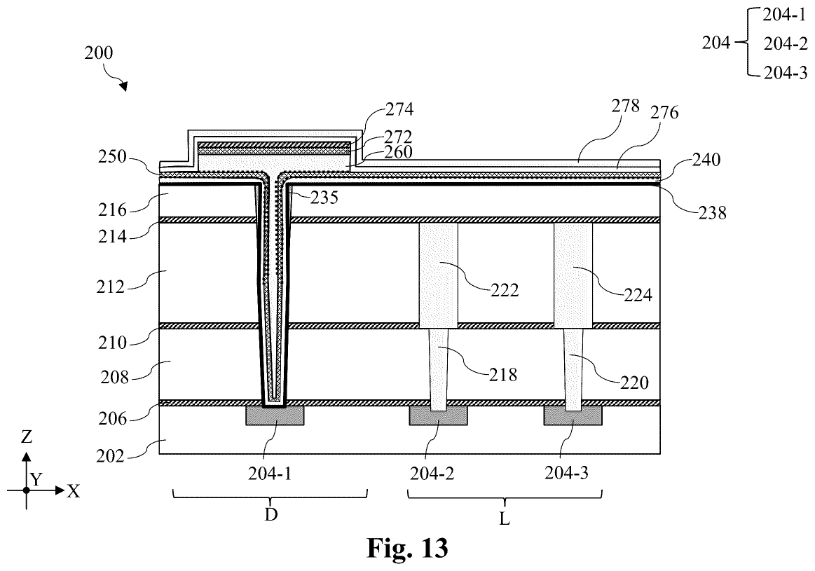

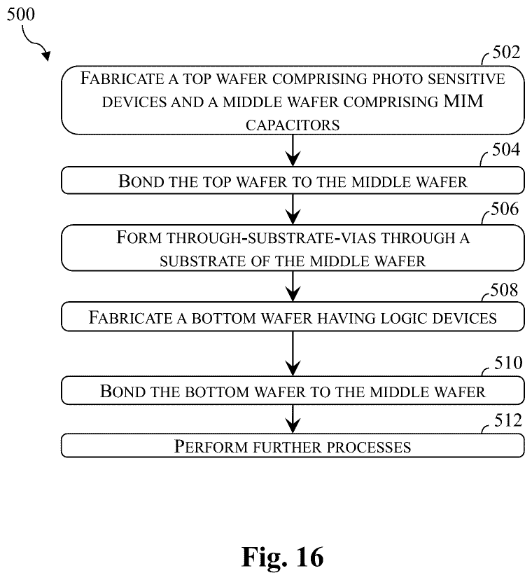

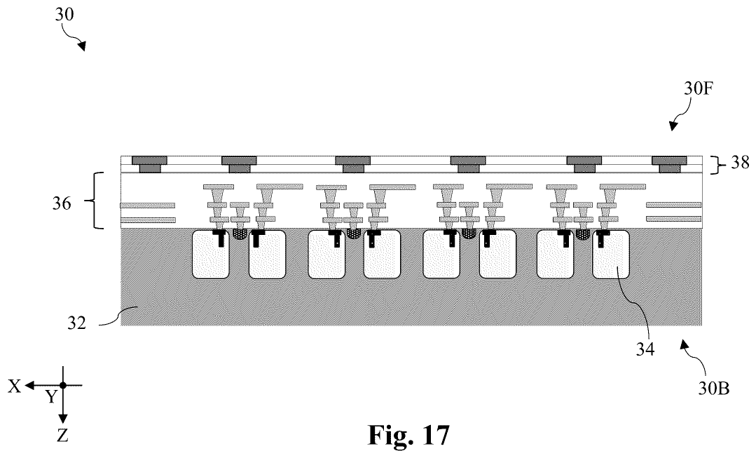

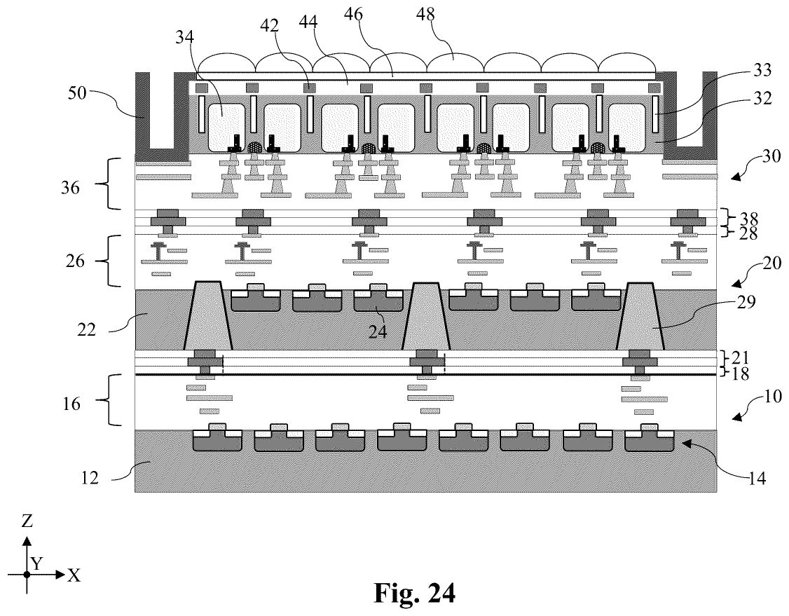

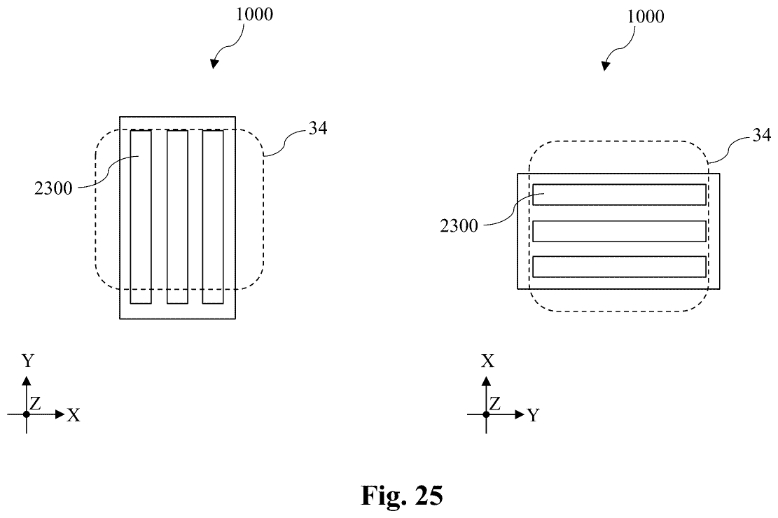

The various aspects of the present disclosure will now be described in more detail with reference to the figures. In that regard, FIG. 1 is a flowchart illustrating method 100 of forming an MIM capacitor according to embodiments of the present disclosure. Method 100 is merely an example and is not intended to limit the present disclosure to what is explicitly illustrated in method 100. Additional steps may be provided before, during and after method 100, and some steps described can be replaced, eliminated, or moved around for additional embodiments of the method. Not all steps are described herein in detail for reasons of simplicity. Method 100 is described below in conjunction with FIGS. 2-15, which are fragmentary cross-sectional views of a workpiece 200 at different stages of fabrication according to embodiments of method 100. Because the workpiece 200 will be fabricated into a semiconductor structure 200 upon conclusion of the fabrication processes, the workpiece 200 may be referred to as the semiconductor structure 200 as the context requires. FIG. 16 is a flowchart illustrating method 500 of forming a CIS according to embodiments of the present disclosure. Method 500 is merely an example and is not intended to limit the present disclosure to what is explicitly illustrated in method 500. Additional steps may be provided before, during and after method 500, and some steps described can be replaced, eliminated, or moved around for additional embodiments of the method. Not all steps are described herein in detail for reasons of simplicity. Method 500 is described below in conjunction with FIGS. 17-23, which are fragmentary cross-sectional views of a top wafer, a middle wafer, a bottom wafer, or a stacked wafer structure thereof at different stages of fabrication according to embodiments of method 500. The middle wafer includes MIM capacitors formed using method 100. From a top view, the MIM capacitors on the middle wafer may be trim-type capacitors shown in FIG. 24 or comb-type capacitors shown in FIG. 25. Additionally, throughout the present application, like reference numerals denote like features, unless otherwise excepted.

Referring to FIGS. 1 and 2, the method 100 includes a block 102 where a workpiece 200 is received. The workpiece 200 includes a bottom dielectric layer 202, metal contacts 204 disposed in the bottom dielectric layer 202, a first etch stop layer (ESL) 206 disposed over the metal contacts 204, a first intermetal dielectric (IMD) layer 208 disposed over the first ESL 206, a second ESL 210 disposed over the first IMD layer 208, a second IMD layer 212 over the second ESL 210, a third ESL 214 over the second IMD layer 212, and a third IMD layer 216 over the third ESL 214. The bottom dielectric layer 202 may include silicon oxide. In the depicted embodiments, the metal contacts 204 include a first metal contact 204-1, a second metal contact 204-2, and a third metal contact 204-3. In some embodiments, the metal contacts 204 include copper (Cu). While not explicitly shown in FIG. 2, a barrier layer may be disposed between the metal contacts 204 and the bottom dielectric layer 202 to prevent electromigration of copper in the metal contacts 204. The barrier layer may include titanium (Ti), titanium nitride (TiN), tantalum (Ta), tantalum nitride (TaN), or a combination thereof. The first IMD layer 208, the second IMD layer 212, and the third IMD layer 216 may share the same composition with the bottom dielectric layer 202. In some embodiments, the first IMD layer 208, the second IMD layer 212, and the third IMD layer 216 may include silicon oxide. The first ESL 206 and the third ESL 214 have a composition different from that of the second ESL 210. In some embodiments, the first ESL 206 and the third ESL 214 include silicon carbide while the second ESL 210 include silicon nitride. The different compositions of the ESLs allow better etch selectivity when a lower ESL is being etched through. In the depicted embodiments, the first IMD layer 208, the second ESL 210, the second IMD layer 212, and the third ESL 214 provide the dielectric structure of a metal layer in an interconnect structure. The metal layer includes contact vias defined in the first IMD layer 208 and also metal lines defined in the second IMD layer 212.

In the depicted embodiments, the first metal contact 204-1 is in a decoupling region D where an MIM capacitor is going to be formed. The second metal contact 204-2 and the third metal contact 204-3 are in a logic region L where signals are passed down directly without going through an MIM capacitor. As shown in FIG. 2, the workpiece 200 includes a first via 218 coupled to the second metal contact 204-2 and a first metal line 222 disposed on and electrically coupled to the first via 218. Similarly, a second via 220 is coupled to the third metal contact 204-3 and a second metal line 224 is disposed on the second via 220. In some embodiments illustrated in FIG. 2, the first via 218, the first metal line 222, the second via 220, and the second metal line 224 are already formed in the workpiece 200 when the workpiece 200 is received. In some embodiments, the first via 218 extends through the first IMD layer 208 and the first ESL 206 to couple to the second metal contact 204-2. The second via 220 extends through the first IMD layer 208 and the first ESL 206 to couple to the second metal contact 204-2. The first metal line 222, extending lengthwise along the Y direction, is disposed in the second ESL 210 and the second IMD layer 212. The first metal line 222 lands on and is electrically coupled to the first via 218. The second metal line 224, extending lengthwise along the Y direction, is disposed in the second ESL 210 and the second IMD layer 212. The second metal line 224 lands on and is electrically coupled to the second via 220.

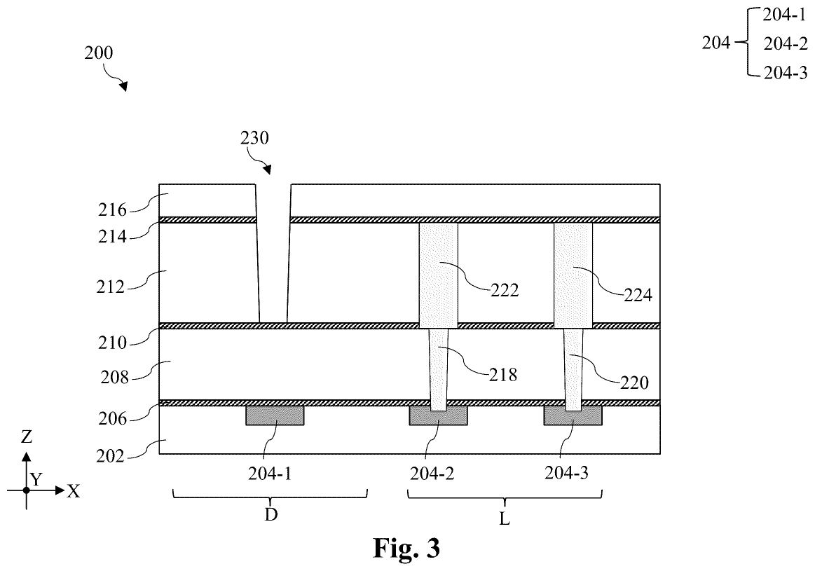

Referring to FIGS. 1 and 3, the method 100 includes a block 104 where a pilot trench opening 230 is formed through the third IMD layer 216, the third ESL 214, and the second IMD layer 212. While not explicitly shown in the figures, the formation of the pilot trench opening 230 may include photolithography processes and etch processes. The photolithography processes form an etch mask that includes a trench-shape opening that passes directly over the first metal contact 204-1. To form the etch mask, at least one hard mask layer is formed over the third IMD layer 216 and a photoresist layer is deposited over the at least one hard mask layer. The at least one hard mask layer may include silicon oxide, silicon nitride, or both. The photoresist layer is first patterned using a photolithography process and then the patterned photoresist layer is then applied as an etch mask to pattern the at least one hard mask layer. The patterned at least one hard mask layer serves as the etch mask to form the pilot trench opening 230. A dry etch process is then performed to etch through the third IMD layer 216, the third ESL 214, and the second IMD layer 212. An example dry etch process for block 104 may include use of nitrogen (N₂), hydrogen (H₂), a hydrocarbon species (e.g. CH₄), a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. It is noted that while the dry etch process at block 104 is substantially anisotropic in nature and etches laterally at a slower rate, it may still etch laterally to increase a width of the pilot trench opening 230 along the X direction.

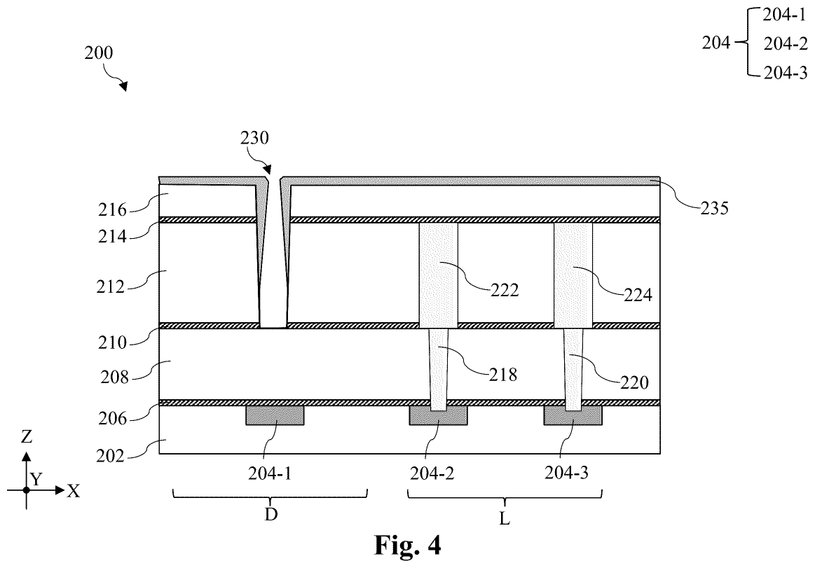

Referring to FIGS. 1 and 4, the method 100 includes a block 106 where an overhanging protection layer 235 is formed over the pilot trench opening 230. The deposition of the overhanging protection layer 235 serves to protect sidewalls of the pilot trench opening 230 to control the lateral etching described above. In the depicted embodiment, the overhanging protection layer 235 is deposited using a deposition method that is less conformally and does not fill holes well. For example, the overhanging protection layer 235 may be deposited using chemical vapor deposition (CVD), plasma enhanced CVD (PECVD), or even physical vapor deposition (PVD). It is noted that the overhanging protection layer 235 may not be satisfactorily deposited using atomic layer deposition (ALD) because the overhanging protect layer 235 deposited using ALD may completely fill the pilot trench opening 230, instead of accumulating around edges of the pilot trench opening 230 shown in FIG. 4. In fact, the overhanging protection layer 235 formed at block 106 is characterized by accumulation of the protection layer 235 that overhangs over the pilot trench opening 230. The accumulation of the overhanging protection layer 235 around the edges of the pilot trench opening 230 protects upper sidewalls of the pilot trench opening 230 before the pilot trench opening 230 is further extended downward at block 108. As shown in FIG. 4, while the overhanging protection layer 235 is deposited over a top surface of the third IMD layer 216 and an upper portion of the sidewalls of the pilot trench opening 230, at least a lower portion of the pilot trench opening 230 is substantially free of the overhanging protection layer 235. In some embodiments, the overhanging protection layer 235 may also be referred to as the overhanging cap layer 235 or simply the cap layer 235. The overhanging protection layer 235 has a composition different from that of the third IMD layer 216, the second IMD layer 212, and the first IMD layer 208. In some instances, the overhanging protection layer 235 may include silicon nitride while the third IMD layer 216, the second IMD layer 212, and the first IMD layer 208 are formed of silicon oxide. In some examples, silicon oxide may be etched at a rate 9 to 10 times of that silicon nitride is etched. In other words, an etch selectivity of silicon oxide relative to silicon nitride may be between about 9 and 10.

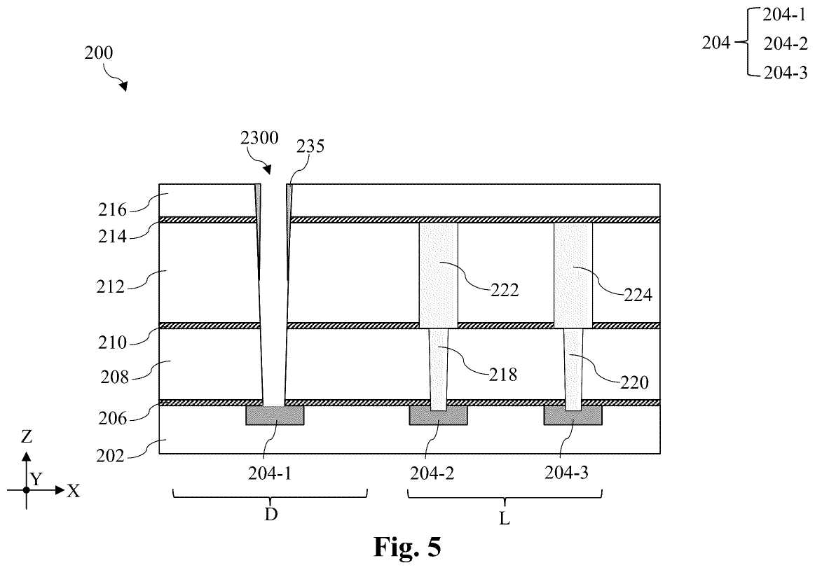

Referring to FIGS. 1 and 5, the method 100 includes a block 108 where the pilot trench opening 230 is extended through the second ESL 210, the first IMD layer 208, and the first ESL 206 to form a deep trench opening 2300 that exposes the first metal contact 204-1. With the overhanging protection layer 235 protecting upper sidewalls of the pilot trench opening 230, a dry etch process may be performed to extends the pilot trench opening 230 through the second ESL 210, the first IMD layer 208, and the first ESL 206 to expose the first metal contact 204-1. The resulting trench shown in FIG. 5 may be referred to as the final trench opening 2300. An example dry etch process for block 108 may include use of nitrogen (N₂), hydrogen (H₂), a hydrocarbon species (e.g. CH₄), a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), a bromine-containing gas (e.g., HBr and/or CHBr₃), an iodine-containing gas, other suitable gases and/or plasmas, and/or combinations thereof. As illustrated in FIG. 5, the etch at block 108 may remove the overhanging protection layer 235 on the top surface of the third IMD layer 216 and thin the overhanging protection layer 235 in the pilot trench opening 230. The final trench opening 2300 in FIG. 5 extends through 6 vertically stacked dielectric layers, including the third IMD layer 216, the third ESL 214, the second IMD layer 212, the second ESL 210, the first IMD layer 208, and the first ESL 206. In other embodiments, in order for the resulting MIM capacitor to have sufficient capacitance, the final trench opening 2300 should at least extend through 3 vertically stacked dielectric layers, such as two IMD layers and one ESL or two ESLs and one IMD layer.

While only one overhanging protection layer 235 is formed as shown in FIGS. 4 and 5, more than one overhanging protection layer may be formed if the pilot trench opening needs to be extended through additional IMD layers and ESLs. For example, after the extension of the pilot trench opening 230 at block 108, another overhanging protection layer may be deposited before the pilot trench opening is extended further downwards. It should be appreciated that the method 100 fully envisions embodiments where more than one overhanging protection layer is formed.

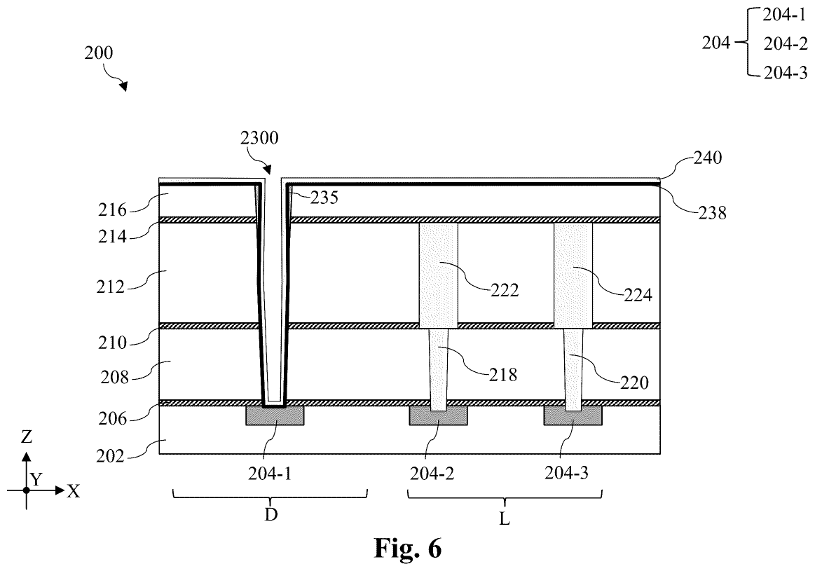

Referring to FIGS. 1 and 6, the method 100 includes a block 110 where a bottom electrode layer 240 is deposited over the deep trench opening 2300. In some embodiment, in order to prevent electromigration, a trench barrier layer 238 may be deposited over the workpiece 200 (including the final trench opening 2300) before the deposition of the bottom electrode layer 240. The trench barrier layer 238 may include tantalum (Ta), tantalum nitride (TaN), or a combination thereof. In one embodiment, the trench barrier layer 238 includes a tantalum nitride (TaN) layer in contact with sidewalls and the first metal contact 204-1 and a tantalum (Ta) layer on the tantalum nitride (TaN) layer. After the deposition of the trench barrier layer 238, the bottom electrode layer 240 is deposited using ALD. In some embodiments, the bottom electrode layer 240 includes titanium nitride (TiN) and a thickness between about 200A and about 500A. The bottom electrode layer 240 serves as a bottom conductor plate of the MIM capacitor to be formed.

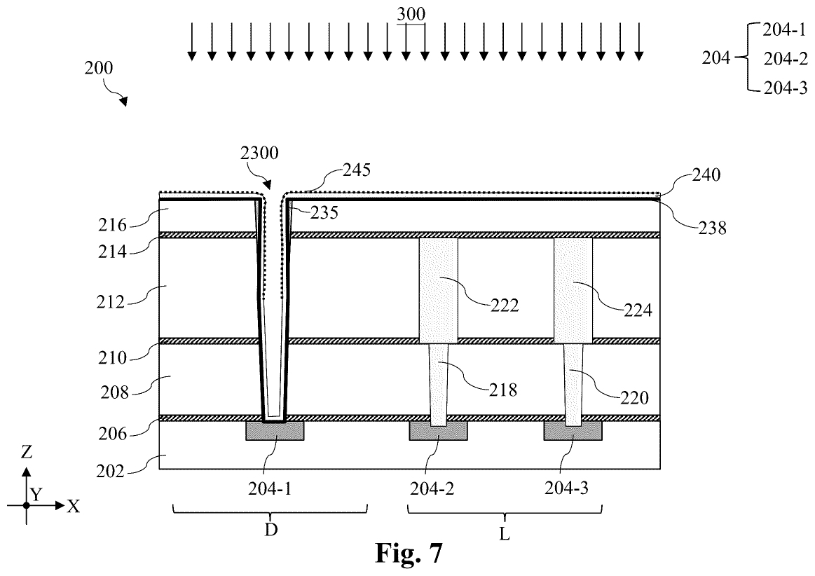

Referring to FIGS. 1 and 7, the method 100 includes a block 112 where a first etch back 300 is performed to trim the deposited bottom electrode layer 240. To make room for the subsequent layers to be deposited in the final trench opening 2300, the deposited bottom electrode layer 240 is etched back in a controlled manner. In an example process, the exposed bottom electrode layer 240 is treated with oxygen to form a surface region that is more susceptible for the following etch process. The workpiece 200 is then etched using a gaseous etchant that will form a gaseous product with the oxygen-treated surface region. In some embodiments, the etching at block 112 may include use of tungsten pentachloride (WCl₅). When tungsten pentachloride is used, tungsten residue 245 may be left behind on surfaces of the etched bottom electrode layer 240. The presence of tungsten residue may be detected using energy-dispersive X-ray fluorescence (XRF).

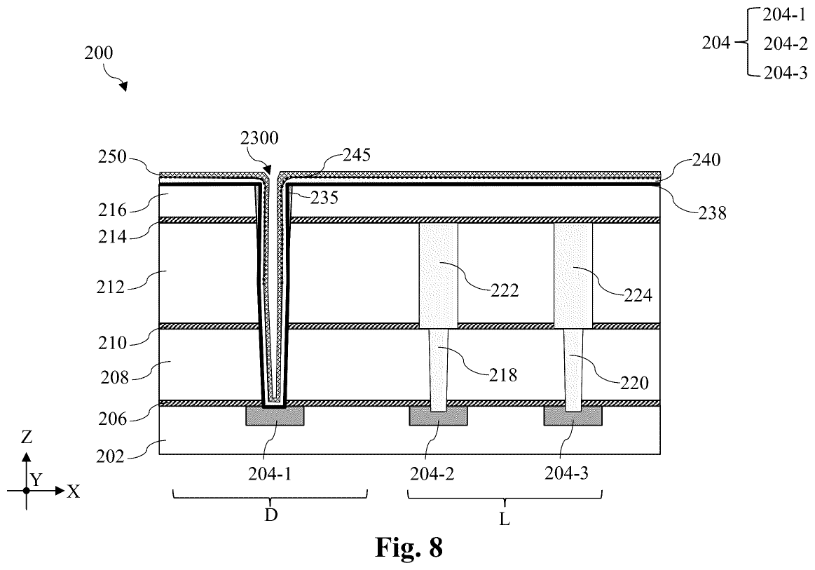

Referring to FIGS. 1 and 8, the method 100 includes a block 114 where an insulator layer 250 is deposited over the bottom electrode layer 240. The insulator layer 250 may include zirconium oxide, aluminum oxide, or a combination thereof. In one embodiment, the insulator layer 250 includes a first zirconium oxide layer in contact with the bottom electrode layer 240, an aluminum oxide layer on the first zirconium oxide layer, and a second zirconium oxide layer on the aluminum oxide layer. Such an insulator layer 250 may also be referred to have a ZrO—AlO—ZrO structure or a ZAZ structure. The insulator layer 250 may be formed using different methods. In one embodiment, zirconium oxide, aluminum oxide, and zirconium oxide are sequentially deposited using ALD. In another embodiment, a first zirconium-containing layer is first deposited using PVD, CVD, or ALD and then oxidized in presence of oxygen to form the a first zirconium oxide layer. An aluminum-containing layer is deposited on the first zirconium oxide layer using PVD, CVD, or ALD and then oxidized in presence of oxygen to form an aluminum oxide layer. Then, a second zirconium-containing layer is deposited on the aluminum oxide layer using PVD, CVD, or ALD and then oxidized in presence of oxygen to form the a second zirconium oxide layer. Example zirconium-containing layer may include a zirconium layer or a zirconium nitride layer. Example aluminum-containing layer may include an aluminum layer or an aluminum nitride layer. In some instances, a total thickness of the insulator layer 250 may be between about 50 Å and about 60 Å.

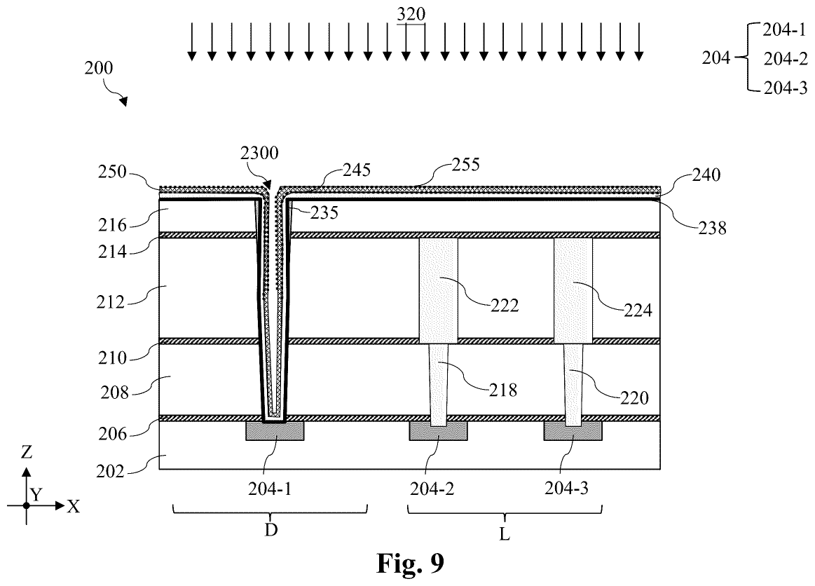

Referring to FIGS. 1 and 9, the method 100 includes a block 116 where a second etch back 320 is performed to trim the deposited insulator layer 250. To make room for the subsequent layers to be deposited in the final trench opening 2300, the deposited insulator layer 250 is etched back in a controlled manner. In an example process, the exposed insulator layer 250 is treated with oxygen to form a surface region that is more susceptible for the following etch process. The workpiece 200 is then etched using a gaseous etchant that will form a gaseous product with the oxygen-treated surface region. In some embodiments, the etching at block 116 may include use of tungsten pentachloride (WCl₅). When tungsten pentachloride is used, tungsten residue 255 may be left behind on surfaces of the etched insulator layer 250. The presence of tungsten residue may be detected using energy-dispersive X-ray fluorescence (XRF).

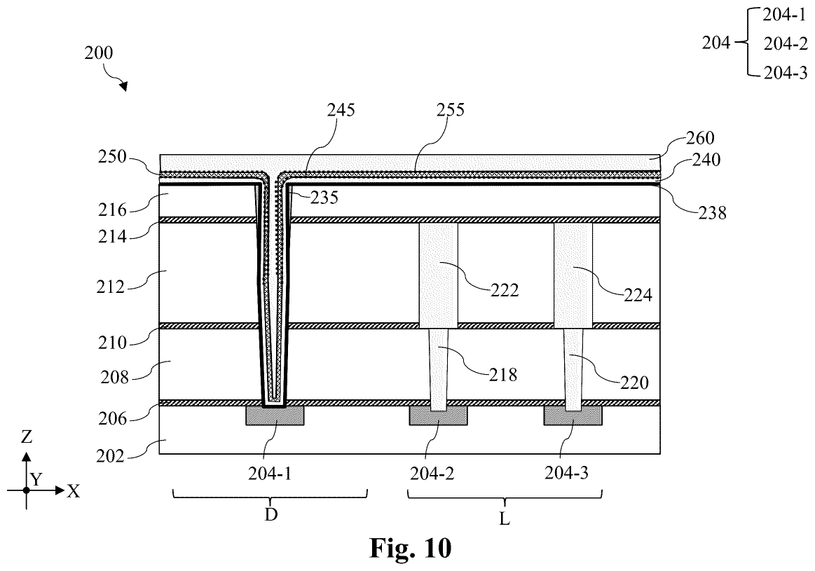

Referring to FIGS. 1 and 10, the method 100 includes a block 118 where a top electrode layer 260 is deposited over the insulator layer 250. In some embodiments, the top electrode layer 260 is conformally deposited over the insulator layer 250 using ALD. In some embodiments, the top electrode layer 260, like the bottom electrode layer 240, includes titanium nitride (TiN) and a thickness between about 400A and about 500A. In one embodiment, the top electrode layer 260 is thicker than the bottom electrode layer 240 to provide a satisfactory landing area for an overlying contact via. The top electrode layer 260 serves as a top conductor plate of the MIM capacitor to be formed.

Referring to FIGS. 1, 11 and 12, the method 100 includes a block 120 where the top electrode layer 260 is patterned. In order to prevent shorting between the bottom electrode layer 240 and the top electrode layer 260, method 100 patterns the bottom electrode layer 240 and the top electrode layer 260 in separate steps. In the depicted embodiments, a first mask layer 272 and a second mask layer 274 are sequentially deposited over the top electrode layer 260 before the patterning of the top electrode layer 260. In some embodiments, the first mask layer 272 includes high-k dielectric materials, such as zirconium oxide, aluminum oxide, or a combination thereof and the second mask layer 274 includes silicon oxynitride or silicon nitride. The first mask layer 272 and the second mask layer 274 protect the top electrode layer 260 during the patterning process. The patterning process at block 120 may include photolithography processes and etching processes. In an example process, a photoresist layer is deposited on the second mask layer 274. The photoresist layer is then patterned by exposure to a radiation source and development in a developer solution. The patterned photoresist layer is then used as an etch mask to etch the second mask layer 274 and the first mask layer 272. The patterned first mask layer 272 and second mask layer 274 are then used as an etch mask to etch the top electrode layer 260 until a portion of the insulator layer 250 are exposed. The etching or patterning of the first mask layer 272 and the second mask layer 274 may include use of use of nitrogen (N₂), hydrogen (H₂), a hydrocarbon species (e.g. CH₄), a fluorine-containing gas (e.g., CF₄, SF₆, CH₂F₂, CHF₃, and/or C₂F₆), other suitable gases and/or plasmas, and/or combinations thereof. The etching or patterning of the top electrode layer 260 may include use of a chlorine-containing gas (e.g., Cl₂, CHCl₃, CCl₄, and/or BCl₃), a bromine-containing gas (e.g., HBr and/or CHBr₃, an iodine-containing gas, other suitable gases and/or plasmas, and/or combinations thereof.

Referring to FIGS. 1, 13 and 14, the method 100 includes a block 122 where the insulator layer 250 and the bottom electrode layer 240 are patterned. After the top electrode layer 260 is patterned at block 120, the insulator layer 250 and the bottom electrode layer 240 are patterned. In the depicted embodiments, a third mask layer 276 and a fourth mask layer 278 are sequentially deposited over the patterned top electrode layer 260 and the exposed insulator layer 250. In some embodiments, the third mask layer 276 includes silicon oxide and the fourth mask layer includes silicon nitride. The patterning process at block 122 may include photolithography processes and etching processes. In an example process, a photoresist layer is deposited on the fourth mask layer 278. The photoresist layer is then patterned by exposure to a radiation source and development in a developer solution. The patterned photoresist layer is then used as an etch mask to etch the third mask layer 276 and the fourth mask layer 278. The patterned third mask layer 276 and fourth mask layer 278 are then used as an etch mask to etch the insulator layer 250, the bottom electrode layer 240, and the trench barrier layer 238 until a portion of the third IMD layer 216 is exposed. The etching or patterning of the third mask layer 276, the fourth mask layer 278 and the insulator layer 250 may include use of use of nitrogen (N₂), hydrogen (H₂), a hydrocarbon species (e.g. CH₄), a fluorine-containing gas (e.g., CF₄, SF₆, CH₂F₂, CHF₃, and/or C₂F₆), other suitable gases and/or plasmas, and/or combinations thereof. The etching or patterning of the bottom electrode layer 240 and the trench barrier layer 238 may include use of a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof.

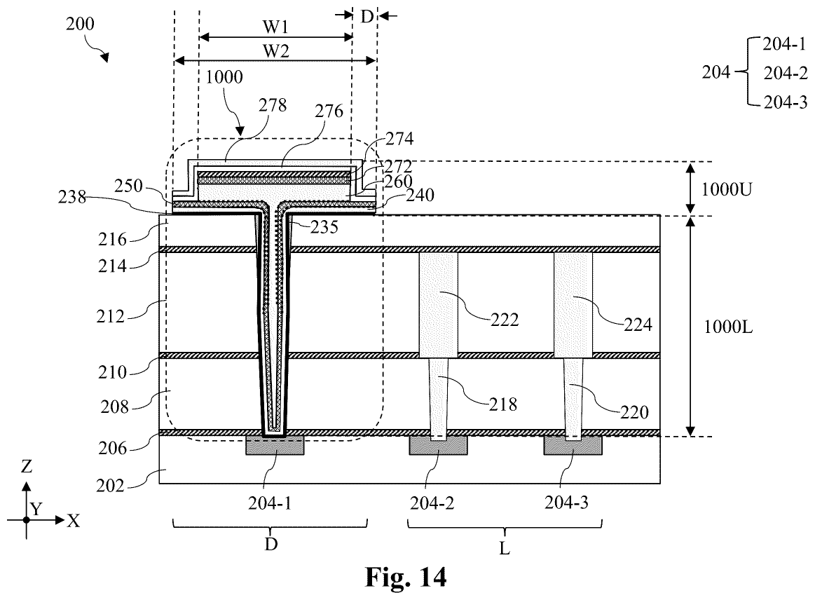

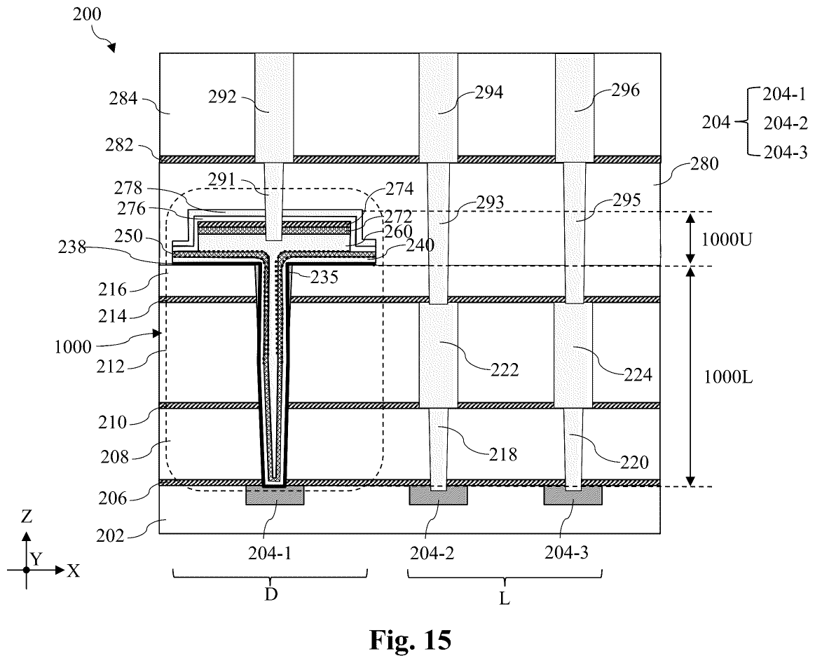

Upon completion of the operations at block 122, an MIM capacitor 1000 is substantially formed. As shown in FIG. 14, the MIM capacitor 1000 includes a lower portion 1000L and an upper portion 1000U disposed on the lower portion 1000L. The lower portion 1000L extends lengthwise along the Y direction and vertically through the third IMD layer 216, the third ESL 214, the second IMD layer 212, the second ESL 210, and first IMD layer 208, and the first ESL 206. The upper portion 1000U extends along a top surface of the third IMD layer 216 and is disposed in a fourth IMD layer 280 shown in FIG. 15. Because the lower portion 1000L of the MIM capacitor 1000 is disposed in a trench, the MIM capacitor 1000 may also be referred to as a deep trench MIM capacitor 1000 or a three-dimensional (3D) MIM capacitor 1000. Tungsten residue 245 is present at the interface between the bottom electrode layer 240 and the insulator layer 250. Tungsten residue 255 is present at the interface between the insulator layer 250 and the top electrode layer 260.

Reference is still made to FIG. 14. It is noted that while the deep trench opening 2300 extends lengthwise along the Y direction, edges of the top electrode layer 260 and the bottom electrode layer 240 are offset by a distance D along the X direction, which is perpendicular to the Y direction. In some embodiments, the distance D may be between about 100 A and about 1000A. This offset functions to prevent undesirable shorting between the top electrode layer 260 and the bottom electrode layer 240 when conductive debris from the etching process is redeposited along the sidewalls of the top electrode layer 260 and the bottom electrode layer 240. It can be seen that when the top electrode layer 260 is patterned, the sidewalls of the bottom electrode layer 240 is covered. When the bottom electrode layer 240 is patterned, the sidewalls of the top electrode layer 260 are already protected by the third mask layer 276 and the fourth mask layer 278. Put differently, the top electrode layer 260 has a first width W1 along the X direction and the bottom electrode layer 240 (as well as the insulator layer 250) has a second width W2 along the X direction. The second width W2 is greater than the first width W1 by 2 times of the distance D.

Referring to FIGS. 1 and 15, the method 100 includes a block 124 where further processes are performed. Such further processes include deposition of additional IMD layers and ESLs and formation of further metal features. In some embodiments depicted in FIG. 15, after the patterning of the insulator layer 250 and the bottom electrode layer 240, a fourth IMD layer 280, a fourth ESL282, and a fifth IMD layer 284 are sequentially deposited over the workpiece 200. The fourth IMD layer 280 are in contact with sidewalls of the trench barrier layer 238, the bottom electrode layer 240, the third mask layer 276, and the fourth mask layer 278, as well as the top surface of the third IMD layer 216. The fourth ESL 282 is deposited on the top surface of the fourth IMD layer 280 and the fifth IMD layer 284 is deposited on the top surface of the fourth ESL 282. In some embodiments, a composition of the fourth IMD layer 280 and the fifth IMD layer 284 may be the same as that of the first IMD layer 208. The fourth ESL 282 may share the same composition with the second ESL 210. In some embodiments, the fourth ESL 282 includes silicon nitride. At block 124, a dual damascene process may be performed to form the vias and metal lines disposed in the fourth IMD layer 280, fourth ESL 282 and the fifth IMD layer 284. In the depicted embodiments, a third via 291 is formed through the fourth IMD layer 280, the fourth mask layer 278, the third mask layer 276, the second mask layer 274, and the first mask layer 272 to contact the top electrode layer 260. As shown in FIG. 15, the third via 291 may partially extends into the top electrode layer 260. A fourth via 293 is formed through the fourth IMD layer 280 and the third ESL 214 to contact the first metal line 222. A fifth via 295 is formed through the fourth IMD layer 280 and the third ESL 214 to contact the second metal line 224. A third metal line 292 is formed through the fourth ESL 282 and the fifth IMD layer 284 to contact a top surface of the third via 291. A fourth metal line 294 is formed through the fourth ESL 282 and the fifth IMD layer 284 to contact a top surface of the fourth via 293. A fifth metal line 296 is formed through the fourth ESL 282 and the fifth IMD layer 284 to contact a top surface of the fifth via 295. The vias and metal lines shown in FIG. 15 include copper. While not explicitly shown in FIG. 15, the vias and metal lines are spaced apart from the IMD layers and ESLs by a barrier layer. The barrier layer may include titanium nitride (TiN), titanium (Ti), tantalum nitride (TaN), or tantalum (Ta).

FIG. 16 is a flowchart illustrating method 500 of forming a CIS according to embodiments of the present disclosure. More specifically, method 500 is configured to form a CIS that has a three-wafer construction. The CIS formed using method 500 includes a bottom wafer, a middle wafer over the bottom wafer, and a top wafer over the middle wafer. As will be described further below, the middle wafer includes MIM capacitors 1000 formed using method 100 described above.

Referring to FIGS. 16, 17 and 18, method 500 includes a block 502 where a top wafer 30 and a middle wafer 20 are fabricated. FIG. 17 illustrates a top wafer 30, which includes a pixel chip. The top wafer 30 includes a third substrate 32 and a third interconnect structure 36. For ease of reference, the top wafer 30 includes a front side 30F adjacent the third interconnect structure 36 and a back side 30B adjacent the third substrate 32. The third substrate 32 may be a bulk silicon (Si) substrate. Alternatively, the third substrate 32 may include elementary semiconductor, such as germanium (Ge); a compound semiconductor, such as silicon carbide (SiC), gallium arsenide (GaAs), gallium phosphide (GaP), indium phosphide (InP), indium arsenide (InAs), and/or indium antimonide (InSb); an alloy semiconductor, such as silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); or combinations thereof.

The third substrate 32 includes a plurality of photodiodes 34. To form the photodiodes 34 in the third substrate 32, the third substrate 32 can include various doped regions. In one embodiment, the third substrate 32 may include n-type dopants, such as phosphorus (P), arsenic (As), or other n-type dopants. The third interconnect structure 36 includes a plurality of metal layers. Each of the plurality of metal layers includes contact vias and metal lines disposed in at least one etch stop layer and at least one IMD layer. The contact vias and metal lines may include copper and barrier layers formed of titanium, titanium nitride, tantalum, or tantalum nitride. The etch stop layers in the third interconnect structure 36 may include silicon nitride, silicon carbide, silicon oxynitride, or a combination thereof. The IMD layer may include silicon oxide.

The top wafer 30 includes a fourth bonding layer 38 deposited on the front side 30F of the top wafer 30. That is, the fourth bonding layer 38 is deposited on the third interconnect structure 36 and provides bonding surfaces and allows inter-substrate communication. In some embodiments represented in FIG. 17 the fourth bonding layer 38 includes a plurality of bonding contacts disposed in a dielectric bonding layer. The dielectric bonding layer may include silicon oxide or silicon oxynitride. The plurality of bonding contacts may include copper (Cu), tantalum (Ta), nickel (Ni), cobalt (Co), aluminum (Al), a combination thereof, or an alloy thereof. In one embodiment, the plurality of bonding contacts include copper (Cu).

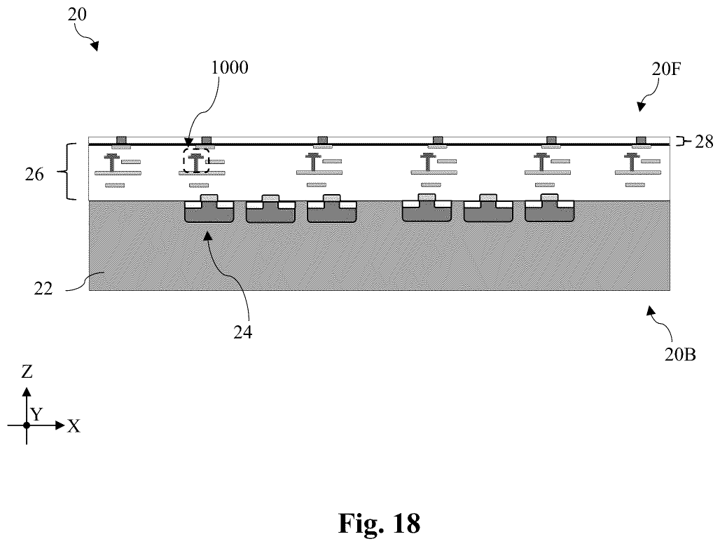

FIG. 18 illustrates a middle wafer 20, which may include MIM capacitors 1000 described above. The middle wafer 20 includes a second substrate 22 and a second interconnect structure 26. For ease of reference, the middle wafer 20 includes a front side 20F adjacent the second interconnect structure 26 and a back side 20B adjacent the second substrate 22. The second substrate 22 may be a bulk silicon (Si) substrate. Alternatively, the second substrate 22 may include elementary semiconductor, such as germanium (Ge); a compound semiconductor, such as silicon carbide (SiC), gallium arsenide (GaAs), gallium phosphide (GaP), indium phosphide (InP), indium arsenide (InAs), and/or indium antimonide (InSb); an alloy semiconductor, such as silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); or combinations thereof.

In some embodiments depicted in FIG. 18, the second substrate 22 includes transistors 24 to serve as row selector transistors, source follower transistors, or reset transistors. The transistors 24 may be implemented using planar transistors or multi-gate transistors. Example multi-gate transistors may include fin-like field effect transistor (FinFETs) or gate-all-around (GAA) transistors. A planar transistor includes a gate structure that may induce a planar channel region along one surface of its active region, hence its name. A FinFET includes a fin-shaped active region arising from a substrate and a gate structure disposed over a top surface and sidewalls of the fin-shaped active region. A GAA transistor includes at least one channel member extending between two source/drain features and a gate structure that wraps completely around the at least one channel member. Because its gate structure wraps around the channel member, a GAA transistor may also be referred to as a surrounding gate transistor (SGT). Depending on the shapes and orientation, a channel member in a GAA transistor may be referred to as a nanosheet, a semiconductor wire, a nanowire, a nanostructure, a nano-post, a nano-beam, or a nano-bridge. In some instances, a GAA transistor may be referred to by the shape of the channel member. For example, a GAA transistor having one or more nanosheet channel member may also be referred to as a nanosheet transistor or a nanosheet FET. In some embodiments not illustrated in the figures, the second substrate 22 may not include any transistors 24 as the transistors are moved to the top wafer 10.

The second interconnect structure 26 includes a plurality of metal layers. Each of the plurality of metal layers includes contact vias and metal lines disposed in at least one etch stop layer and at least one intermetal dielectric (IMD) layer. The contact vias and metal lines may include copper and barrier layers formed of titanium, titanium nitride, tantalum, or tantalum nitride. The etch stop layers in the second interconnect structure 26 may include silicon nitride, silicon carbide, silicon oxynitride, or a combination thereof. The IMD layer may include silicon oxide. As shown in FIG. 18, a plurality of MIM capacitors 1000 are disposed in the second interconnect structure 26. Each of the MIM capacitors 1000 extends through more than one metal layer. Details of the MIM capacitor 1000 are described above with references to FIGS. 14 and 15.

The middle wafer 20 includes a second bonding layer 28 deposited on the front side 20F of the middle wafer 20. That is, the second bonding layer 28 is deposited on the second interconnect structure 26 and provides bonding surfaces and allows inter-substrate communication. In some embodiments represented in FIG. 18, the second bonding layer 28 includes a plurality of bonding contacts disposed in a dielectric bonding layer. The dielectric bonding layer may include silicon oxide or silicon oxynitride. The plurality of bonding contacts may include copper (Cu), tantalum (Ta), nickel (Ni), cobalt (Co), aluminum (Al), a combination thereof, or an alloy thereof. In one embodiment, the plurality of bonding contacts include copper (Cu).

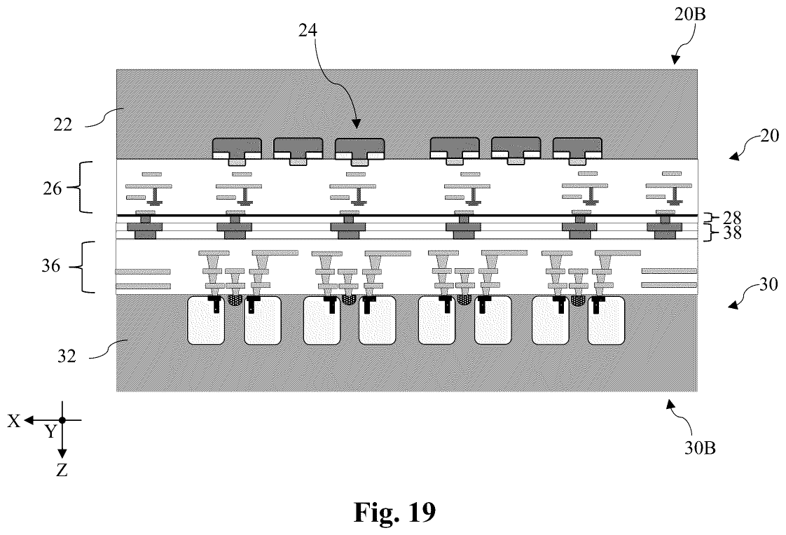

Referring to FIGS. 16 and 19, method 500 includes a block 504 where the top wafer 30 is bonded to the middle wafer 20. Operations at block 504 include flipping over the middle wafer 20 shown in FIG. 18 and bonding the same to the top wafer 30 shown in FIG. 17. To bond the middle wafer 20 to the top wafer 30, each of the bonding contacts in the second bonding layer 28 is aligned to one of the bonding contacts in the fourth bonding layer 38. A direct bonding process is then performed to bond the middle wafer 20 to the top wafer 30 such that, as described further below, dielectric surfaces are bonded to dielectric surfaces and metal surfaces are bonded to metal surfaces. To ensure a strong bonding between the second bonding layer 28 and the fourth bonding layer 38, surfaces of the second bonding layer 28 and the fourth bonding layer 38 are cleaned to remove organic and metallic contaminants. In an example process, a sulfuric acid hydrogen peroxide mixture (SPM), a mixture of ammonium hydroxide and hydrogen peroxide (SC1), or both may be used to remove organic contaminants on the second bonding layer 28 and the fourth bonding layer 38. A mixture of hydrochloric acid and hydrogen peroxide (SC2) may be used to remove metallic contaminants. Besides cleaning, the bonding contacts may be treated by an argon plasma or a nitrogen plasma to activate the surfaces thereof. After the bonding contacts in the fourth bonding layer 38 and the second bonding layer 28 are aligned, an anneal is performed to promote the van der Waals force bonding of the dielectric bonding layers as well as the surface-activated bonding (SAB) of the bonding pads and the bonding contacts.

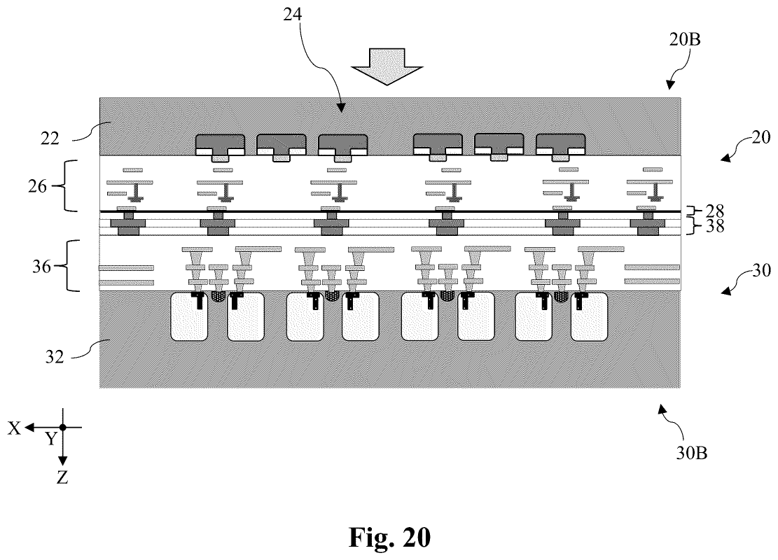

Referring to FIGS. 16, 20 and 21, method 500 includes a block 506 where through-substrate-vias (TSVs) 29 are formed through the second substrate 22 of the middle wafer 20. Operations at block 506 include thinning of the second substrate 22 of the middle wafer 20 and formation of the TSVs 29 through the thinned second substrate 22. Referring to FIG. 20, the second substrate 22 of the middle wafer 20 is thinned. The chip stack shown in FIG. 20, which includes the top wafer 30 and the middle wafer 20, may undergo multiple thinning and polishing steps to reduce the thickness of the second substrate 22. In an example process, diamond wheels may be used to perform coarse grinding, fine grinding, or super fine grinding and a chemical mechanical polishing (CMP) process may be performed to polishing the ground second substrate 22. The thinning of the second substrate 22 helps reduce the aspect ratio of the TSV openings for the TSVs 29 (to be described below).

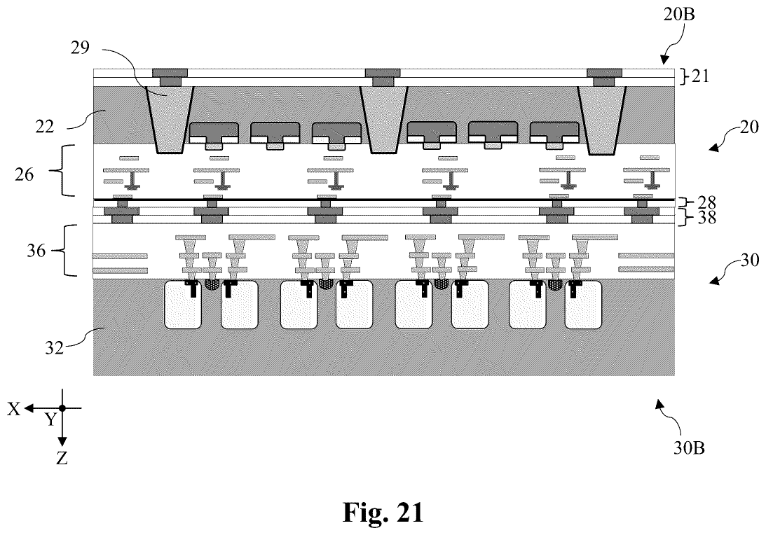

Referring to FIG. 21, after the second substrate 22 is thinned, through-substrate-vias 29 are formed through the second substrate 22. The TSVs 29 function to redirect electrical signals to the back side 20B of the middle wafer 20 to interface a third bonding layer 21. In an example process, via openings are formed through the second substrate 22 using dry etching, such as reactive-ion-etching (RIE). After the via openings are formed, a conductive material is then deposited in the via openings to form the TSVs 29. The conductive material may include copper (Cu). To prevent electromigration of coppers, the via openings may be lined with a barrier layer before deposition of the conductive material. In some instances, the barrier layer may include titanium nitride.

After the formation of the TSVs 29, a third bonding layer 21 is formed over the thinned second substrate 22. The third bonding layer 21 includes a plurality of bonding contacts disposed in a dielectric bonding layer. The dielectric bonding layer may include silicon oxide or silicon oxynitride. The plurality of bonding contacts may include copper (Cu), tantalum (Ta), nickel (Ni), cobalt (Co), aluminum (Al), a combination thereof, or an alloy thereof. In one embodiment, the plurality of bonding contacts include copper (Cu). Furthermore, each of the plurality of bonding contacts is vertically aligned with one of the TSVs 29.

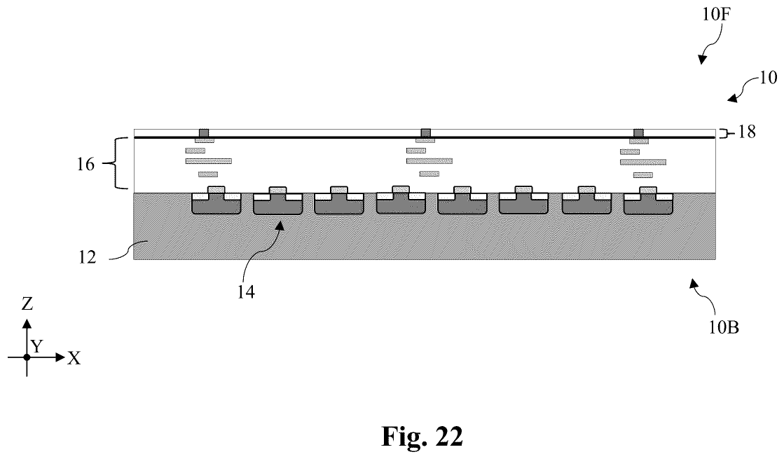

Referring to FIGS. 16 and 22, method 500 includes a block 508 where a bottom wafer 10 is fabricated. The bottom wafer 10 includes a logic chip and may be referred to as a logic wafer 10. The bottom wafer 10 includes a first interconnect structure 16 and a first substrate 12 disposed over the first interconnect structure 16. For ease of reference, the bottom wafer 10 includes a front side 10F adjacent the first interconnect structure 16 and a back side 10B adjacent a surface of the first substrate 12. The first substrate 12 may be a bulk silicon (Si) substrate. Alternatively, the first substrate 12 may include elementary semiconductor, such as germanium (Ge); a compound semiconductor, such as silicon carbide (SiC), gallium arsenide (GaAs), gallium phosphide (GaP), indium phosphide (InP), indium arsenide (InAs), and/or indium antimonide (InSb); an alloy semiconductor, such as silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); or combinations thereof. The first substrate 12 includes a plurality of logic transistors 14. The logic transistors 14 may be implemented using planar transistors or multi-gate transistors. Example multi-gate transistors may include fin-like field effect transistor (FinFETs) or gate-all-around (GAA) transistors. A planar transistor includes a gate structure that may induce a planar channel region along one surface of its active region, hence its name. A FinFET includes a fin-shaped active region arising from a substrate and a gate structure disposed over a top surface and sidewalls of the fin-shaped active region. A GAA transistor includes at least one channel member extending between two source/drain features and a gate structure that wraps completely around the at least one channel member. Because its gate structure wraps around the channel member, a GAA transistor may also be referred to as a surrounding gate transistor (SGT). Depending on the shapes and orientation, a channel member in a GAA transistor may be referred to as a nanosheet, a semiconductor wire, a nanowire, a nanostructure, a nano-post, a nano-beam, or a nano-bridge. In some instances, a GAA transistor may be referred to by the shape of the channel member. For example, a GAA transistor having one or more nanosheet channel member may also be referred to as a nanosheet transistor or a nanosheet FET.

The first interconnect structure 16 includes a plurality of metal layers. Each of the plurality of metal layers includes contact vias and metal lines disposed in at least one etch stop layer and at least one intermetal dielectric (IMD) layer. The contact vias and metal lines may include copper and barrier layers formed of titanium, titanium nitride, tantalum, or tantalum nitride. The etch stop layers in the first interconnect structure 16 may include silicon nitride, silicon carbide, silicon oxynitride, or a combination thereof. The IMD layer may include silicon oxide.

The bottom wafer 10 includes a first bonding layer 18 deposited on the front side 10F of the bottom wafer 10. That is, the first bonding layer 18 is deposited on the first interconnect structure 16 and provides bonding surfaces and allows inter-substrate communication. In some embodiments represented in FIG. 22, the first bonding layer 18 includes a plurality of bonding contacts disposed in a dielectric bonding layer. The dielectric bonding layer may include silicon oxide or silicon oxynitride. The plurality of bonding contacts may include copper (Cu), tantalum (Ta), nickel (Ni), cobalt (Co), aluminum (Al), a combination thereof, or an alloy thereof. In one embodiment, the plurality of bonding contacts include copper (Cu).

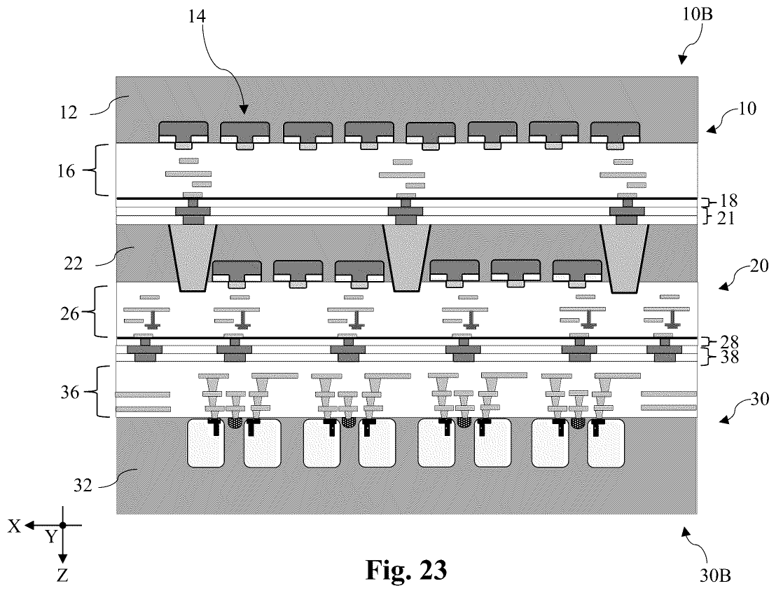

Referring to FIGS. 16 and 23, method 500 includes a block 510 where the bottom wafer 10 is bonded to the middle wafer 20. To bond the bottom wafer 10 to the middle wafer 20, each of the bonding contacts in the first bonding layer 18 is aligned to one of the bonding contacts in the third bonding layer 21. A direct bonding process is then performed to bond the bottom wafer 10 to the middle wafer 20 such that, as described below, dielectric surfaces are bonded to dielectric surfaces and metal surfaces are bonded to metal surfaces. To ensure a strong bonding between the first bonding layer 18 and the third bonding layer 21, surfaces of the first bonding layer 18 and the third bonding layer 21 are cleaned to remove organic and metallic contaminants. In an example process, a sulfuric acid hydrogen peroxide mixture (SPM), a mixture of ammonium hydroxide and hydrogen peroxide (SC1), or both may be used to remove organic contaminants on the first bonding layer 18 and the third bonding layer 21. A mixture of hydrochloric acid and hydrogen peroxide (SC2) may be used to remove metallic contaminants. Besides cleaning, the bonding contacts in the first bonding layer 18 and the third bonding layer 21 may be treated by an argon plasma or a nitrogen plasma to activate the surfaces thereof. After the bonding contacts in the first bonding layer 18 and the third bonding layer 21 are aligned, an anneal is performed to promote the van der Waals force bonding of the sixth dielectric bonding layer and the fifth dielectric bonding layer as well as the surface-activated bonding (SAB) of the bonding pads and the bonding contacts.

Referring to FIGS. 16 and 24, method 500 includes a block 512 where further processes are performed to complete the CIS. Such further processes may include thinning of the third substrate 32. After the bottom wafer 10 is bonded to the middle wafer 20, the chip stack shown in FIG. 23 is flipped upside down such that the back side 30B of the top wafer 30 faces up, as shown in FIG. 24. After the flipping over, the third substrate 32 of the top wafer 30 may undergo multiple thinning and polishing steps to reduce the thickness of the third substrate 32. In an example process, diamond wheels may be used to perform coarse grinding, fine grinding, or super fine grinding and a chemical mechanical polishing (CMP) process may be performed to polishing the ground third substrate 32.

The further processes at block 512 also include formation of deep trench isolation (DTI) features 33, formation of a metal grid 42, deposition of passivation layers 44, formation of a color filter layer 46, formation of microlens 48, and formation of metal pads 50. To form the DTI features 33, deep trenches are formed into the third substrate 32 from the back side 30B (see FIG. 23). A liner and a fill material may then be deposited into the deep trenches to form DTI features 33. Because the DTI features 33 are formed over the back side 30B, the DTI features 33 may also be referred to as backside DTI (BDTI) features 33. In some embodiments, the liner may include a metal, such as aluminum (Al), tungsten (W), ruthenium (Ru), cobalt (Co), or copper (Cu) and the fill material may include a dielectric material, such as silicon oxide, aluminum oxide, hafnium oxide, titanium oxide, barium titanate, zirconium oxide, lanthanum oxide, barium oxide, strontium oxide, yttrium oxide, or a combination thereof.

The passivation layers 44 may include, for example, a first passivation layer and a second passivation layer. The composition of the passivation layers 44 may be the same as the composition of the fill material of the DTI features 33. The metal grid 42 may be embedded in the first passivation layer and the second passivation layer. The metal grid 42 is a grid-like structure or framework that extends over several, if not all, of the photodiodes 34. In some embodiments, the metal grid 42 may include tin (Sn), aluminum-copper (AlCu), aluminum (Al), tungsten (W), ruthenium (Ru), cobalt (Co), or copper (Cu). In an example process to form the metal grid 42, a metal layer is deposited over the first passivation layer. Then photolithography process and etch processes are used to pattern the metal layer into the metal grid 42. The second passivation layer is then deposited over the metal grid 42.

The color filter layer 46 may be formed of a polymeric material or a resin that includes color pigments. The color filter layer 46 is formed over the second passivation layer of the passivation layers 44. The color filter layer 46 includes a plurality of filters each allowing for the transmission of radiation (e.g., light) having a specific range of wavelength, while blocking light of wavelengths outside of the specified range. Referring still to FIG. 24, microlens 48 are formed over the color filter layer 46. The microlens 48 may be formed of any material that may be patterned and formed into microlenses, such as a high transmittance acrylic polymer. In an embodiment, a microlens layer may be formed using a material in a liquid state and spin-on techniques. This method has been found to produce a substantially planar surface and a microlens layer having a substantially uniform thickness, thereby providing greater uniformity in the microlens 48. Other methods, such as CVD, PVD, or the like, may also be used. The planar material for the microlens layer may be patterned using a photolithography and etch technique to pattern the planar material in an array of microlens 48 corresponding to the photodiodes 34. The planar material may then be reflowed to form an appropriate curved surface for the microlens 48. The microlens 48 may be cured using an ultraviolet (UV) treatment.

To allow electrical connection through the thickness of the third substrate 32, the third substrate 32 is sawed along scribe lines to form openings that expose contact features in the third interconnect structure 36. Thereafter, a metal layer is deposited over the openings to form the metal pads 50. In some embodiments, the metal layer for the metal pads 50 may include copper (Cu), aluminum (Al), an aluminum-copper (AlCu) alloy, or titanium nitride.

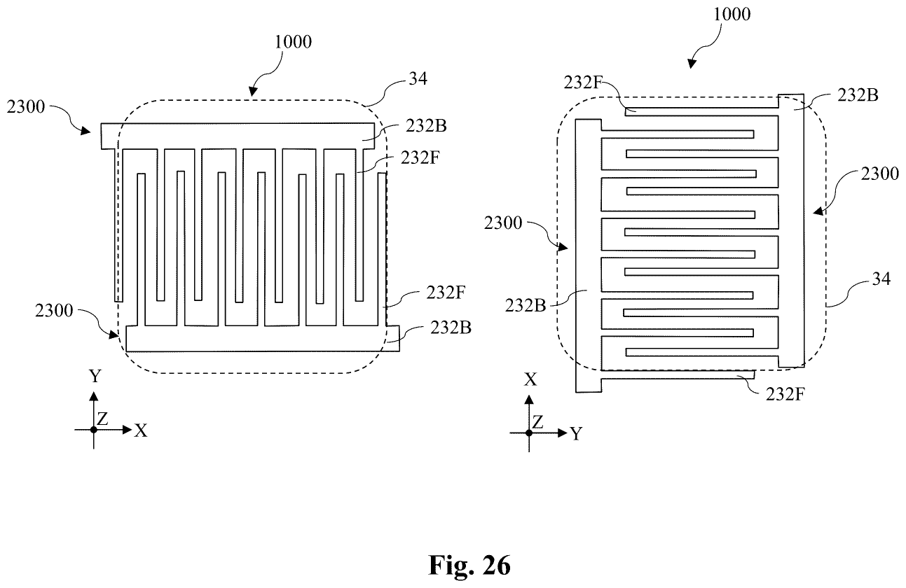

The MIM capacitors 1000 in the middle wafer 20 may come in a trim-type shown in FIG. 25 or a comb-type shown in FIG. 26. As shown in FIG. 25, a trim-type MIM capacitor 1000 includes filled deep trenches 2300 (i.e., deep trench openings 2300 filled with the bottom electrode layer, the insulator layer and the top electrode layer) arranged parallel to one another along either the Y direction or the X direction. In some embodiments, a MIM capacitor 1000 may include a plurality of filled deep trenches 2300, such as three filled deep trenches 2300 shown in FIG. 24. In some implementations, a vertical projection area of a photodiode 34 (shown in dotted lines) in the top wafer 30 may substantially overlap with the MIM capacitor 1000 along the Z direction (i.e., the stacking direction of the bottom wafer 10, the middle wafer 20, and the top wafer 30). As shown in FIG. 26, a comb-type MIM capacitor 1000 includes filled deep trenches 2300 arranged in comb shapes. In some embodiments, a comb-type MIM capacitor 1000 may include at least one comb-shape structure that includes a base portion 232B and a plurality of finger portions 232F stemming perpendicularly from a lateral side of the base portion 232B. The base portion 232B and the plurality of finger portions 232F correspond to an interconnected filled deep trenches 2300. In the depicted embodiments, each of the comb-type MIM capacitors 1000 include two interleaving or complementary comb-shape structures. Referring to FIG. 26, the comb-type MIM capacitors 1000 may include the base portions 232B extending either along the X direction or along the Y direction. In other words, the interleaving finder portions 232 of the comb-type MIM capacitors 100 may extend along either the Y direction or the X direction. In some implementations, a vertical projection area of a photodiode 34 (shown in dotted lines) in the top wafer 30 may substantially overlap with the comb-type MIM capacitor 1000 along the Z direction (i.e., the stacking direction of the bottom wafer 10, the middle wafer 20, and the top wafer 30).

Thus, in some embodiments, the present disclosure provides a semiconductor structure. The semiconductor includes a contact feature disposed in a first dielectric layer, a first etch stop layer (ESL) over the contact feature and the first dielectric layer, a second dielectric layer over the first ESL, a second ESL over the second dielectric layer, a third dielectric layer over the second ESL, a third ESL over the third dielectric layer, a fourth dielectric layer over the third ESL, and a capacitor. The capacitor includes a bottom electrode layer continuously extending along a top surface of the fourth dielectric layer and vertically through the fourth dielectric layer, the third ESL, the third dielectric layer, the second ESL, the second dielectric layer, and the first ESL, an insulator layer disposed over the bottom electrode and extending at least through the fourth dielectric layer and vertically through the fourth dielectric layer, the third ESL, the third dielectric layer, the second ESL, and the second dielectric layer, a top electrode layer disposed over the insulator layer such that the top electrode layer is spaced apart from the bottom electrode layer by the insulator layer.

In some embodiments, tungsten is present at an interface between the bottom electrode layer and the insulator layer as well as at an interface between the insulator layer and the top electrode layer. In some implementations, a composition of the second ESL is different from a composition of the first ESL or the third ESL. In some instances, the first ESL and the third ESL include silicon carbide and the second ESL includes silicon nitride. In some embodiments, the first dielectric layer, the second dielectric layer, the third dielectric layer, and the fourth dielectric layer include silicon oxide. In some instances, the bottom electrode layer and the top electrode layer include titanium nitride. The insulator layer includes zirconium oxide and aluminum oxide. In some embodiments, the semiconductor structure further includes a barrier layer disposed between the bottom electrode layer and the top surface of the fourth dielectric layer as well as between the bottom electrode layer and sidewalls of the first ESL, the second dielectric layer, the second ESL, the third dielectric layer, the third ESL, and the fourth dielectric layer. In some embodiments, the barrier layer includes tantalum or tantalum nitride.

Another aspect of the present disclosure involves a semiconductor structure. The semiconductor structure includes at least three dielectric layers stacked one over another, a bottom electrode layer including a top portion over the at least three dielectric layers and a lower portion extending through the at least three dielectric layers, an insulator layer disposed over the bottom electrode layer and including a top portion over the at least three dielectric layers and a lower portion extending through the at least three dielectric layers, a top electrode layer disposed over the insulator layer and including a top portion over the at least three dielectric layers and a lower portion extending through the at least three dielectric layers. The top portion of the top electrode layer has a first width along a direction and the top portion of the insulator layer has a second width along the direction. The second width is greater than the first width.

In some embodiments, tungsten is present at an interface between the lower portion of bottom electrode layer and the lower portion of the insulator layer as well as at an interface between the lower portion of the insulator layer and the lower portion of the top electrode layer. In some implementations, the semiconductor structure further includes a first mask layer disposed over the top portion of the top electrode layer; and a second mask layer disposed over the first mask layer. The first mask layer includes zirconium oxide or aluminum oxide and the second mask layer includes silicon oxynitride. In some embodiments, the semiconductor structure further includes a third mask layer disposed over the second mask layer and sidewalls of the top portion of the top electrode layer, and a fourth mask layer disposed over the third mask layer. The third mask layer includes silicon oxide and the fourth mask layer includes silicon nitride. In some instances, the bottom electrode layer and the top electrode layer include titanium nitride and the insulator layer includes zirconium oxide and aluminum oxide.

Yet another aspect of the present disclosure involves a method. The method includes receiving a workpiece that includes a metal feature disposed in a first dielectric layer, a second dielectric layer over the metal feature and the first dielectric layer, a first ESL over the second dielectric layer, a third dielectric layer over the first ESL, a second ESL over the third dielectric layer, a fourth dielectric layer over the second ESL, and forming a pilot trench extending through the fourth dielectric layer, the second ESL, the third dielectric layer, depositing a sidewall cap layer over the pilot trench such that the sidewall cap layer overhangs edges of the pilot trench, after the depositing, extending the pilot trench through the first ESL and the second dielectric layer to form a deep trench to expose the metal feature, conformally depositing a bottom electrode layer in the deep trench, conformally depositing an insulator layer over the bottom electrode layer, conformally depositing a top electrode layer over the insulator layer.

In some embodiments, the depositing of the sidewall cap layer is configured such that the sidewall cap layer does not fill the pilot trench. In some implementations, the sidewall cap layer includes silicon nitride. In some instances, the method further includes after the conformally depositing of the bottom electrode layer, treating the bottom electrode layer with oxygen, and after the treating of the bottom electrode layer, etching the bottom electrode layer using tungsten pentachloride. In some instances, the method further includes after the conformally depositing of the insulator layer, treating the insulator layer with oxygen, and after the treating of the insulator layer, etching the insulator layer using tungsten pentachloride. In some embodiments, the method further includes before the conformally depositing of the bottom electrode layer, depositing a barrier layer over sidewalls of the deep trench. The barrier layer includes tantalum, tantalum nitride, or both. In some embodiments, the conformally depositing of the insulator layer includes depositing a first zirconium layer over the deep trench, oxidizing the first zirconium layer to form a first zirconium oxide layer, depositing an aluminum layer over the first zirconium oxide layer, oxidizing the aluminum layer to form an aluminum oxide layer, depositing a second zirconium layer over the aluminum oxide layer, and oxidizing the second zirconium layer to form a second zirconium oxide layer.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure. For example, by implementing different thicknesses for the bit line conductor and word line conductor, one can achieve different resistances for the conductors. However, other techniques to vary the resistances of the metal conductors may also be utilized as well.

What is claimed is:

1. A semiconductor structure, comprising:
a contact feature disposed in a first dielectric layer;
a first etch stop layer (ESL) over the contact feature and the first dielectric layer;
a second dielectric layer over the first ESL;
a second ESL over the second dielectric layer;
a third dielectric layer over the second ESL;
a third ESL over the third dielectric layer;
a fourth dielectric layer over the third ESL; and
a capacitor comprising:
a bottom electrode layer continuously extending along a top surface of the fourth dielectric layer and vertically through the fourth dielectric layer, the third ESL, the third dielectric layer, the second ESL, the second dielectric layer, and the first ESL,
an insulator layer disposed over the bottom electrode and extending at least through the fourth dielectric layer and vertically through the fourth dielectric layer, the third ESL, the third dielectric layer, the second ESL, and the second dielectric layer, and
a top electrode layer disposed over the insulator layer such that the top electrode layer is spaced apart from the bottom electrode layer by the insulator layer.

2. The semiconductor structure of claim 1, wherein tungsten is present at an interface between the bottom electrode layer and the insulator layer as well as at an interface between the insulator layer and the top electrode layer.

3. The semiconductor structure of claim 1, wherein a composition of the second ESL is different from a composition of the first ESL or the third ESL.

4. The semiconductor structure of claim 3,
wherein the first ESL and the third ESL comprise silicon carbide,
wherein the second ESL comprises silicon nitride.

5. The semiconductor structure of claim 1, wherein the first dielectric layer, the second dielectric layer, the third dielectric layer, and the fourth dielectric layer comprise silicon oxide.

6. The semiconductor structure of claim 1,
wherein the bottom electrode layer and the top electrode layer comprise titanium nitride,
wherein the insulator layer comprises zirconium oxide and aluminum oxide.

7. The semiconductor structure of claim 6, further comprising:
a barrier layer disposed between the bottom electrode layer and the top surface of the fourth dielectric layer as well as between the bottom electrode layer and sidewalls of the first ESL, the second dielectric layer, the second ESL, the third dielectric layer, the third ESL, and the fourth dielectric layer.

8. The semiconductor structure of claim 7, wherein the barrier layer comprises tantalum or tantalum nitride.

9. A semiconductor structure, comprising:
at least three dielectric layers stacked one over another;
a bottom electrode layer comprising a top portion over the at least three dielectric layers and a lower portion extending through the at least three dielectric layers;
an insulator layer disposed over the bottom electrode layer and comprising a top portion over the at least three dielectric layers and a lower portion extending through the at least three dielectric layers;
a top electrode layer disposed over the insulator layer and comprising a top portion over the at least three dielectric layers and a lower portion extending through the at least three dielectric layers;
wherein the top portion of the top electrode layer has a first width along a direction and the top portion of the insulator layer has a second width along the direction,
wherein the second width is greater than the first width.

10. The semiconductor structure of claim 9, wherein tungsten is present at an interface between the lower portion of bottom electrode layer and the lower portion of the insulator layer as well as at an interface between the lower portion of the insulator layer and the lower portion of the top electrode layer.

11. The semiconductor structure of claim 9, further comprising:
a first mask layer disposed over the top portion of the top electrode layer; and
a second mask layer disposed over the first mask layer,
wherein the first mask layer comprises zirconium oxide or aluminum oxide,
wherein the second mask layer comprises silicon oxynitride.

12. The semiconductor structure of claim 11, further comprising:
a third mask layer disposed over the second mask layer and sidewalls of the top portion of the top electrode layer; and
a fourth mask layer disposed over the third mask layer,
wherein the third mask layer comprises silicon oxide,
wherein the fourth mask layer comprises silicon nitride.

13. The semiconductor structure of claim 9,
wherein the bottom electrode layer and the top electrode layer comprise titanium nitride,
wherein the insulator layer comprises zirconium oxide and aluminum oxide.

14. A method, comprising:
receiving a workpiece that includes:
a metal feature disposed in a first dielectric layer,
a second dielectric layer over the metal feature and the first dielectric layer,
a first ESL over the second dielectric layer,
a third dielectric layer over the first ESL,
a second ESL over the third dielectric layer, and
a fourth dielectric layer over the second ESL;
forming a pilot trench extending through the fourth dielectric layer, the second ESL, the third dielectric layer;
depositing a sidewall cap layer over the pilot trench such that the sidewall cap layer overhangs edges of the pilot trench;
after the depositing, extending the pilot trench through the first ESL and the second dielectric layer to form a deep trench to expose the metal feature;
conformally depositing a bottom electrode layer in the deep trench;
conformally depositing an insulator layer over the bottom electrode layer; and
conformally depositing a top electrode layer over the insulator layer.

15. The method of claim 14, wherein the depositing of the sidewall cap layer is configured such that the sidewall cap layer does not fill the pilot trench.

16. The method of claim 14, wherein the sidewall cap layer comprises silicon nitride.

17. The method of claim 14, further comprising:
after the conformally depositing of the bottom electrode layer, treating the bottom electrode layer with oxygen; and
after the treating of the bottom electrode layer, etching the bottom electrode layer using tungsten pentachloride.

18. The method of claim 14, further comprising:
after the conformally depositing of the insulator layer, treating the insulator layer with oxygen; and
after the treating of the insulator layer, etching the insulator layer using tungsten pentachloride.

19. The method of claim 14, further comprising:
before the conformally depositing of the bottom electrode layer, depositing a barrier layer over sidewalls of the deep trench,
wherein the barrier layer comprises tantalum, tantalum nitride, or both.

20. The method of claim 14, wherein the conformally depositing of the insulator layer comprises:
depositing a first zirconium layer over the deep trench;
oxidizing the first zirconium layer to form a first zirconium oxide layer;
depositing an aluminum layer over the first zirconium oxide layer;
oxidizing the aluminum layer to form an aluminum oxide layer;
depositing a second zirconium layer over the aluminum oxide layer; and
oxidizing the second zirconium layer to form a second zirconium oxide layer.
